(19) United States
(12) Patent Application Publication
(10) Pub. No.: US 2009/0309236 A1
(43) Pub. Date: Dec. 17, 2009

(54) Package on Package Structure with thin film Interposing Layer

(76) Inventor: Mark Allen Gerber, Lucas, TX (US)

Correspondence Address: TEXAS INSTRUMENTS INCORPORATED, P O BOX 655474, M/S 3999, DALLAS, TX, 75265, US

(21) Appl. No.: 12/140,727

(22) Filed: Jun. 17, 2008

(51) Int. Cl. H01L 23/538

(52) U.S. Cl. 257/777; 257/E23.169

(57) ABSTRACT

The invention relates to microelectronic semiconductor device assemblies having vertically stacked semiconductor device layers. In a disclosed example of a preferred embodiment, a semiconductor device includes a base substrate, an interposing layer, and a second semiconductor device. The interposing layer features a thin insulating film with numerous electrical contacts on its surfaces for electrically coupling with electrical contacts on the adjacent layers. The interposing layer further includes electrical contacts for coupling with one or more non-adjacent layers. Particular examples of preferred embodiments of the invention disclose the use of polyimide film for the interposing layer material and metal studs for non-adjacent layer contacts.

### TECHNICAL FIELD

The invention relates to electronic semiconductor chips and manufacturing. More particularly, the invention relates to systems and associated methods for manufacturing vertically stacked semiconductor device assemblies with improved interposing layers between semiconductor device layers.

### BACKGROUND OF THE INVENTION

There is generally an ongoing need to minimize the size of electronic apparatus. At the same time, the demand for increased features results in an increase in the number of components on a given device. Efforts are continuously being made to design and manufacture devices and packages with reduced area, but attempts to increase density while reducing area eventually reach a practical limit. As designers attempt to maximize the use of substrate, semiconductor device, and system area, vertical stacking of system components becomes increasingly attractive.

In order to reduce or eliminate some of the problems associated with wirebonding and to reduce the footprint of a completed assembly, surface-mountable, or flip-chip, semiconductor devices are sometimes preferred for vertically stacked applications. Generally, semiconductor devices are stacked in such assemblies by mounting the back side of a semiconductor device to an insulating substrate, with exposed surface contacts designed to accept electrical coupling to corresponding surface contacts. In such assemblies, the connection between two semiconductor devices is generally accomplished using an interposing layer made from rigid material, such as an organic substrate, provided with the requisite electrical connections, generally solder balls. One or more additional semiconductor devices may also in turn be stacked in a similar manner to form a multi-layer, multi-device package system containing two, three or more stacked semiconductor devices operably coupled to one another, usually through the package substrate, and usually including provision for external connection elsewhere.

Problems remain in the present state of the art, however. The desirability of reducing the footprint of the assembly, and thus the footprint of each respective layer, is beset with challenges including pitch and layout limitations inherent in forming the interposing layer using a rigid substrate material. The expense of fashioning such an interposing layer is prohibitive in some instances, particularly in applications where fine pitch microbump interconnections are desired. In applications where interlayer vertical connections are desired, efforts to use through-silicon vias in the interposing layer substrate are beset with manufacturing difficulties that rapidly increase the expense of manufacturing as the available area decreases. It is of course desirable to make the interposing layer only as thick as absolutely necessary in order to help minimize the overall height of the assembly. Unfortunately, with the substrate materials used in the arts, a certain minimum thickness is required in order to provide the interposing layer with sufficient mechanical strength to withstand manufacturing and handling operations, and to resist warping. Warping of the overall assembly can be an additional problem, particularly in cases where stack layers of varying areas are used, resulting in overhangs susceptible to warpage. Other considerations, which can lead to further complications, include the need to keep electrical connections short to optimize speed, and to provide design flexibility for addressing layout and timing concerns.

Due to these and other technological problems, improved vertically stacked semiconductor device assemblies and methods for their manufacture would be useful and advantageous contributions to the art. The present invention is directed to overcoming, or at least reducing, problems present in the prior art, and contributes one or more heretofore unforeseen advantages indicated herein.

### SUMMARY OF THE INVENTION

In carrying out the principles of the present invention, in accordance with preferred embodiments thereof, the invention provides novel and useful improvements for vertically stacked semiconductor device assemblies. Through diligent study, experimentation, and analysis, the inventor has determined that thin film interposing layers may be used in order to overcome some of the problems with traditional rigid interposing layers known in the arts. Endeavors to use thin film interposers for vertically coupling layers of semiconductor stack assemblies, in order to reduce the thickness of the assemblies, have led to synergistic innovations in using thin film based interposers to realize further advantages such as increased electrical connection density, improved layout flexibility, reduced manufacturing costs, and in some cases increased mechanical strength and durability. Using the invention, the interposing layer may be provided with a full array of fine pitch of electrical contact pads. Advantages also accrue when contact pads are called for on the periphery only, as they may be provided at a higher density than previously known in the art. Aspects of the invention are directed to making vertical interconnections among layers in a stack assembly without the need for using potentially more complex and expensive through-silicon via technology, increasing design flexibility and reducing manufacturing costs.

According to one aspect of the invention, in an example of a preferred embodiment, a semiconductor device assembly using the invention includes a base substrate having a region for mounting a device and adjacent electrical contacts on its surface. A first semiconductor device has one surface affixed to the device mounting region, and numerous electrical contacts on its opposite surface. An interposing layer is affixed thereto, and the contacts of the first device are electrically connected to suitable contacts on the interposing layer. The interposing layer is made from a thin insulating film or tape material endowed with numerous electrical contacts on its surfaces. A second semiconductor device is likewise attached and electrically connected to the other surface of the interposing layer. The interposing layer also includes a number of electrical contacts suitable for electrically coupling directly with the electrical contacts on the base substrate.

According to another aspect of the invention, in preferred embodiments, the electrical contacts on the interposing layer for electrically coupling directly with the electrical contacts on the base substrate comprise metal studs, wirebond pins, or solder-coated copper inserts.

According to another aspect of the invention, in a vertically stacked semiconductor device assembly incorporating an interposing layer as described, in a preferred embodiment, a third semiconductor device is affixed to the second semiconductor device, having electrical contacts configured for operably coupling directly to electrical contacts on the base substrate.

According to another aspect of the invention, in an example of a preferred embodiment, a semiconductor device assembly includes electrical contacts on a second surface of the interposing layer configured for operably coupling directly to electrical contacts on the third semiconductor device.

According to still another aspect of the invention, an interposing layer for use between stacked devices in a stacked semiconductor device assembly includes a thin insulating film or tape supporting a plurality of electrical contacts on each of its surfaces for coupling with contacts on adjacent semiconductor device layers of the stack. On at least one of the interposing layer surfaces, electrical contacts configured for operably coupling directly to contacts on a non-adjacent layer of the stack are also included.

According to yet another aspect of the invention, in preferred embodiments, the electrical contacts on the interposing layer for electrically coupling directly with electrical contacts on a non-adjacent layer of the stack are made using for example, metal studs, wirebond studs, or solder-coated copper.

The invention has advantages including but not limited to one or more of the following: decreased footprint in package on package structures; decreased interposing layer thickness; increased versatility in assembly component selection; improved interlayer connections; reduced warpage; and reduced cost. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view of an example of a preferred embodiment of a vertically stacked semiconductor device assembly according to the invention;

FIG. 2 is a cutaway side view of an example of an alternative preferred embodiment of a vertically stacked semiconductor device assembly according to the invention;

FIG. 3 is a cutaway side view of another example of an alternative preferred embodiment of a vertically stacked semiconductor device assembly according to the invention; and

FIG. 4 is a cutaway side view of another example of a preferred embodiment of a vertically stacked semiconductor device assembly according to the invention.

The drawings are not to scale, and some features of embodiments shown and discussed are simplified or amplified for illustrating principles and features, as well as anticipated and unanticipated advantages of the invention.

### DESCRIPTION OF PREFERRED EMBODIMENTS

While the making and using of various exemplary embodiments of the invention are discussed herein, it should be appreciated that the present invention provides inventive concepts which can be embodied in a wide variety of specific contexts. It should be understood that the invention may be practiced with vertically stacked semiconductor package on package assemblies and associated manufacturing processes of various types and materials without altering the principles of the invention. For purposes of clarity, detailed descriptions of functions and systems familiar to those skilled in the semiconductor device, packaging, and manufacturing arts are not included.

In general, the invention provides vertically stacked semiconductor device assemblies using thin film or tape interposing layers structured for vertically coupling layers of the stack. Features of the invention are advantageous in terms of increased electrical connection density, decreased assembly footprint, decreased assembly thickness, and even increased mechanical strength and durability due to improved vertical connections among stack components.

Referring initially to FIG. 1, a cutaway view of an example of a vertically stacked semiconductor device assembly 10 according to a preferred embodiment of the invention is shown. A base substrate 12 has on its surface 14 a region 16 adapted for receiving a first semiconductor device 18 permanently mounted by one surface 20, i.e., its back side. The first semiconductor device 18 has numerous electrical contacts 22 on its opposing surface 24, i.e., the surface not attached to the base substrate 12. Preferably, microbump contacts 22 as known in the arts for high density surface mounting are used for making operable electrical connections among the circuitry (not shown) within the first semiconductor device 18 and suitable conductive paths (not shown) provided in the interposing layer 26. In place of microbumps, other surface-mountable contacts such as solder pads may also be used. Additionally, a plurality of electrical contacts 28 are disposed adjacent to the region 16 on the surface of the base substrate 12 to which the first semiconductor device 18 is mounted. The first semiconductor device 18 is overlain by, and attached to, the interposing layer 26. The interposing layer 26 is structured around a relatively thin tape or film of insulating material 30, preferably polyimide film for example, adapted to supporting a plurality of electrical contacts 32, 34. As shown in FIG. 1, contacts 32 on a first surface 36 of the interposing layer 26 are configured to correspond with the electrical contacts 22 of the first semiconductor device 18. Contacts 34 on a second surface 38 of the interposing layer 28 are configured to correspond with electrical contacts 40 on the surface 42 of a second semiconductor device 44. The second semiconductor device 44 is permanently attached to the second surface 38 of the interposing layer 26, preferably using microbumps or solder balls for providing operable electrical connections among their respective circuitry (not shown). The interposing layer 26 also includes a number of electrical contacts 46, e.g., preferably pre-formed metal studs, although metal pins formed by wirebonding or solder-coated copper balls may also be used, on its first surface 36 configured for operably coupling directly to the electrical contacts 28 on the base substrate 12 surface 14 adjacent to the device mounting area 16.

As shown and described, the interposing layer 26 used in implementing the invention is preferably made from a foundation 30 of polyimide film or similar material. Such film, or tape, is preferred generally for its insulating properties, temperature resistance, strength, flexibility, chemical and electrical properties, and thinness relative to more rigid alternative materials. Thicknesses ranging from about 1 to 10 mil are available in the arts and may be used, with the thinner films typically preferred for the implementation of the invention. The surface contacts, e.g., 32, 34, on the interposing layer 26 are preferably surface-mount contacts of various configurations known in the arts, typically exposed copper, gold, or suitable conductive alloy microbumps or bond pads. The metal studs 46 are preferably formed from suitable metals, such as gold, copper, or alloy, using common metallurgical bonding techniques for the formation of single studs, or pins, as shown 46, for making operable electrical connections directly to contacts on a non-adjacent layer, e.g. 12, of the assembly 10. It should also be appreciated by those skilled in the arts, that solder balls or double pins (not shown) may also be used in some applications. The use of thin film 30 for the interposing layer 26 permits the use of finer pitch surface contacts, e.g. 22, 32, 34, as well as a thinner interposing layer 26, ultimately resulting in a thinner stacked package assembly 10. Using the thin-film structure, a finer pitch may be used between the metal studs 46 than with alternatives known in the arts. Another unexpected advantage of the invention, due to the mechanical properties provided by having more numerous vertical studs, solder balls or pins among stack layers, is increased rigidity in some applications, providing package on package assemblies with increased resistance to warpage. Encapsulant and/or underfill material (not shown) may also be used to mechanically bond stack components as known in the arts.

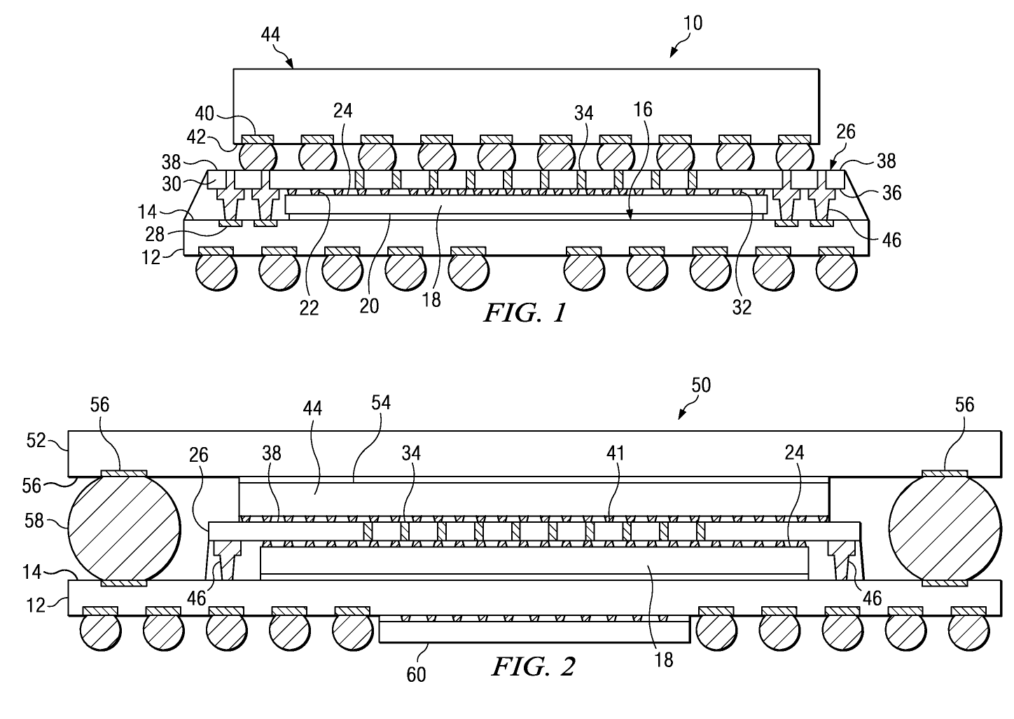

Now referring primarily to FIG. 2, an example of an alternative preferred embodiment of the invention is shown in a cutaway view, in which a vertically stacked package on package assembly 50 includes a third semiconductor device 52. The third semiconductor device 52 is affixed to the upper (as shown in the drawings) surface 54 of a second semiconductor device 44. The third semiconductor device 52 also has a number of electrical contacts 56 disposed in an arrangement suitable for making operable electrical couplings, solder balls 58 in this example, directly to electrical contacts 28 on the base substrate 12. In addition to, or in place of, solder balls 58, metal studs or pins may also be used. In most other respects, the assembly 50 shown in FIG. 2 is similar in structure to that described with respect to FIG. 1, using an interposing layer 26 between first 18 and second 44 semiconductor devices. In the example of FIG. 2, microbump electrical connections 22, 41, are shown between the interposing layer 26 and the first 18 and second 44 semiconductor devices. Solder ball connections may be used as well. In the exemplary embodiment of FIG. 2, one possible use of the invention is shown, in which the use of microbump connections 22, 41 provided by the interposing layer 26 facilitate the stacked assembly 50 including a processor chip 18, such as a multi-core digital signal processor for example, on the base substrate 12, topped by a fine pitch device, such as a Wide I/O SDRAM (synchronous dynamic random access memory) chip 44, with a modem chip 60 mounted on the other side of the base substrate 12. The components are preferably configured to work in concert, along with additional functionality and/or memory contained in the third semiconductor device 52. Thus, the invention provides a package on package assembly 50 with useful advantages in terms of profile, footprint, connection density, cost, and speed, and also a surprising degree of warpage resistance due to the inclusion of metal studs 46 on the interposing layer 26, and in some cases also due to the electrical connections provided between the base substrate and third device, providing vertical mechanical connections among components of the stack. Dielectric encapsulant or underfill (not shown) is preferably introduced in order to provide increased strength and protection as known in the arts.

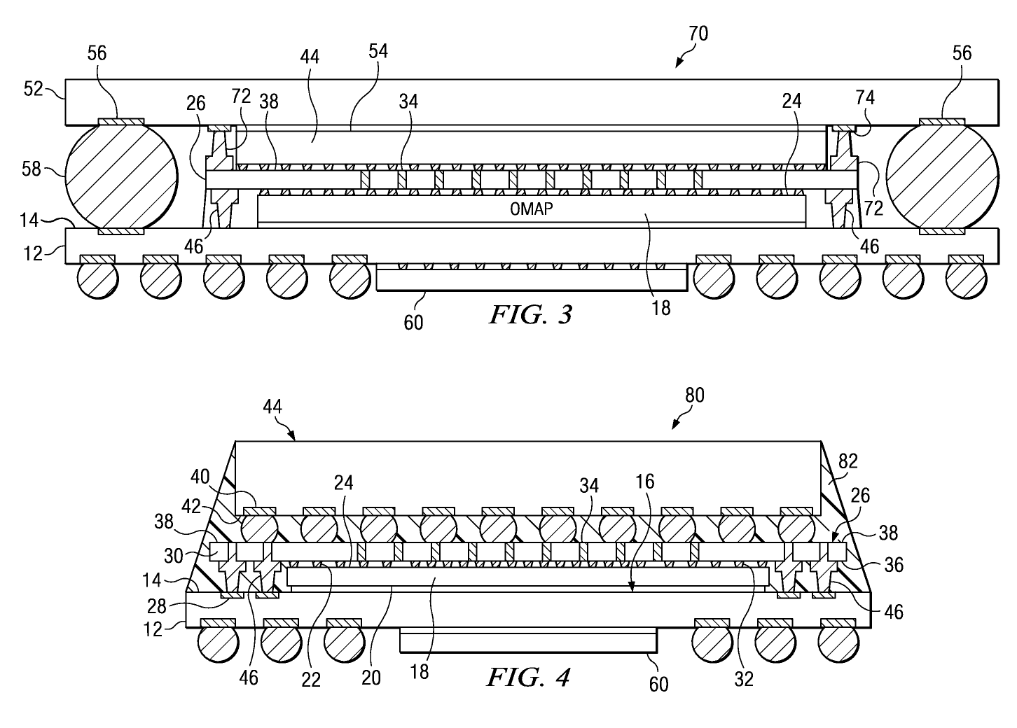

The possible variations of implementations of the invention are many and cannot, and need not, all be shown. An additional example of a preferred embodiment is provided in FIG. 3. A semiconductor device assembly 70 is shown having much in common with that shown in, and described with reference to, FIGS. 1 and 2. Additionally, the interposing layer 26 in this embodiment of the invention includes metal studs 72 extending from its upper (in the drawings) surface 38 to a third semiconductor device 52 where suitable contact pads 74 have been provided. This capability may provide additional advantages, for example, in applications where it is desirable to have the design flexibility to enable electrical connections between the second device 38 and the third device 52, and/or between the first device 18 and third device 52, without the necessity of routing the signal through the base substrate 12. Thus, the illustrated adaptation of the interposing layer 26 of the invention is exhibited to possess unexpected advances in terms of design flexibility and speed potential in addition to other advantages referenced herein.

An additional alternative embodiment of the invention is shown in FIG. 4. As illustrated in this cutaway side view, the invention may be used in a stacked package assembly 80 including one or more additional layers 60 on the side of the base substrate 12 opposite the first semiconductor device 14. Dielectric encapsulant 82 is preferably provided to form a protective package body as is common in the arts, as is also preferred in the other variations of the invention described herein. The encapsulant is omitted from the other figures for illustration purposes.

The methods and systems of the invention provide one or more advantages including but not limited to surprisingly effective reduction of warpage in stacked packages, increased pitch, reduced footprint, reduced thickness, increased speed, increased design flexibility in assembly configuration, and reduced costs. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

I claim:

1. A semiconductor device assembly comprising:
a base substrate, the base substrate having a device mounting region and a plurality of adjacent electrical contacts;
a first semiconductor device having one surface affixed to the mounting region of the base substrate, and having a plurality of electrical contacts on an opposing surface;
a second semiconductor device having a plurality of electrical contacts on at least one surface;
an interposing layer further comprising a thin insulating film supporting a plurality of electrical contacts, contacts on a first surface configured to correspond with electrical contacts of the first semiconductor device, and contacts on a second surface configured to correspond with electrical contacts of the second semiconductor device; wherein,
the first surface of the interposing layer is operably coupled to the first semiconductor device, and the second surface of the interposing layer is operably coupled to the second semiconductor device; and
the interposing layer further comprising a plurality of electrical contacts on its first surface operably coupled directly to the electrical contacts on the base substrate.

2. The semiconductor device assembly according to claim 1 wherein the plurality of electrical contacts on the first surface of the interposing layer for operably coupling directly to electrical contacts on the base substrate further comprise metal studs.

3. The semiconductor device assembly according to claim 1 wherein the plurality of electrical contacts on the first surface of the interposing layer for operably coupling directly to electrical contacts on the base substrate further comprise metal wirebond pins.

4. The semiconductor device assembly according to claim 1 wherein the plurality of electrical contacts on the first surface of the interposing layer for operably coupling directly to electrical contacts on the base substrate further comprise solder-coated copper.

5. The semiconductor device assembly according to claim 1 wherein the interposing layer further comprises polyimide tape.

6. The semiconductor device assembly according to claim 1 further comprising a third semiconductor device affixed to the second semiconductor device and having electrical contacts configured for operably coupling directly to electrical contacts on the base substrate.

7. The semiconductor device assembly according to claim 1 further comprising:
a plurality of electrical contacts on the second surface of the interposing layer configured for operably coupling directly to electrical contacts on a third semiconductor device affixed to the second semiconductor device.

8. The semiconductor device assembly according to claim 1 further comprising:
a plurality of electrical contacts on the second surface of the interposing layer configured for operably coupling directly to electrical contacts on a third semiconductor device affixed to the second semiconductor device;
wherein said plurality of electrical contacts further comprise metal studs.

9. The semiconductor device assembly according to claim 1 further comprising:
a plurality of electrical contacts on the second surface of the interposing layer configured for operably coupling directly to electrical contacts on a third semiconductor device affixed to the second semiconductor device;
wherein said plurality of electrical contacts further comprise metal wirebond pins.

10. The semiconductor device assembly according to claim 1 further comprising:
a plurality of electrical contacts on the second surface of the interposing layer configured for operably coupling directly to electrical contacts on a third semiconductor device affixed to the second semiconductor device;
wherein said plurality of electrical contacts further comprise solder-coated copper.

11. A semiconductor device assembly comprising:
a base substrate, the base substrate having a device mounting region and a plurality of electrical contacts disposed adjacent thereto;
a first semiconductor device having one surface affixed to the mounting region of the base substrate, and having a plurality of electrical contacts on an opposing surface;
a second semiconductor device having a plurality of electrical contacts on at least one surface;
an interposing layer further comprising a thin insulating film supporting a plurality of electrical contacts, contacts on a first surface configured to correspond with electrical contacts of the first semiconductor device, and contacts on a second surface configured to correspond with electrical contacts of the second semiconductor device; wherein,
the first surface of the interposing layer is operably coupled to the first semiconductor device, and the second surface of the interposing layer is operably coupled to the second semiconductor device; and wherein
the interposing layer further comprises a plurality of electrical contacts on its first surface configured for operably coupling directly to the electrical contacts on the base substrate; and
a third semiconductor device affixed to the second semiconductor device and having electrical contacts configured for operably coupling directly to electrical contacts on the base substrate.

12. The semiconductor device assembly according to claim 11 wherein the plurality of electrical contacts on the first surface of the interposing layer configured for operably coupling directly to electrical contacts on the base substrate further comprise metal studs.

13. The semiconductor device assembly according to claim 11 wherein the plurality of electrical contacts on the first surface of the interposing layer configured for operably coupling directly to electrical contacts on the base substrate further comprise metal wirebond pins.

14. The semiconductor device assembly according to claim 11 wherein the plurality of electrical contacts on the first surface of the interposing layer configured for operably coupling directly to electrical contacts on the base substrate further comprise solder-coated copper.

15. The semiconductor device assembly according to claim 11 wherein the interposing layer comprises polyimide film.

16. The semiconductor device assembly according to claim 11 further comprising:
a plurality of electrical contacts on the second surface of the interposing layer configured for operably coupling directly to electrical contacts on the third semiconductor device.

17. The semiconductor device assembly according to claim 11 further comprising:
a plurality of electrical contacts on the second surface of the interposing layer configured for operably coupling directly to electrical contacts on the third semiconductor device;
wherein said electrical contacts further comprise metal studs.

18. The semiconductor device assembly according to claim 11 further comprising:
a plurality of electrical contacts on the second surface of the interposing layer configured for operably coupling directly to electrical contacts on the third semiconductor device;
wherein said electrical contacts further comprise metal wirebond pins.

19. The semiconductor device assembly according to claim 11 further comprising:
a plurality of electrical contacts on the second surface of the interposing layer configured for operably coupling directly to electrical contacts on the third semiconductor device;
wherein said electrical contacts further comprise solder-coated copper.

20. For use between stacked devices in a stacked semiconductor device assembly, an interposing layer comprising:
a thin insulating film supporting a plurality of electrical contact pads on each of its surfaces for operably coupling with contacts on an adjacent semiconductor device layer of the stack; and
on at least one of its surfaces, a plurality of electrical contacts configured for operably coupling directly to contacts on a non-adjacent layer of the stack.

21. The semiconductor device assembly interposing layer according to claim 20 wherein the plurality of electrical contacts configured for operably coupling directly to contacts on a non-adjacent layer of the stack further comprise metal studs.

22. The semiconductor device assembly interposing layer according to claim 20 wherein the plurality of electrical contacts configured for operably coupling directly to contacts on a non-adjacent layer of the stack further comprise metal wirebond pins.

23. The semiconductor device assembly interposing layer according to claim 20 wherein the plurality of electrical contacts configured for operably coupling directly to contacts on a non-adjacent layer of the stack further comprise solder-coated copper.

24. The semiconductor device assembly interposing layer according to claim 20 wherein the interposing layer comprises a thin insulating film of polyimide material.
